(19) United States
(12) Patent Application Publication
(10) Pub. No.: US 2025/0306638 A1
(43) Pub. Date: Oct. 2, 2025

(54) ELECTRONIC DEVICE AND BAND

(71) Applicant: Lenovo (Beijing) Limited, Beijing (CN)

(72) Inventors: Zhenling ZHANG, Beijing (CN); Keda XING, Beijing (CN); Heng LI, Beijing (CN); Xiaoyong HUANG, Beijing (CN)

(21) Appl. No.: 19/059,234

(22) Filed: Feb. 20, 2025

(30) Foreign Application Priority Data
Mar. 29, 2024 (CN) 202410383172.5

(51) Int. Cl. G06F 1/16

(52) U.S. Cl. CPC G06F 1/1652

(57) ABSTRACT

An electronic device includes a first body, a connector, a second body connected to the first body through the connector, a deformable screen including a first part fixed to the first body, a second part fixed to the second body, and a deformation part between the first part and the second part, and a deformable band covering an edge of the deformation part and including a first deformation arm including a plurality of first teeth facing toward the screen and a second deformation arm including a plurality of second teeth facing toward the screen. The first body includes a first frame covering an edge of the first part, and the second body includes a second frame covering an edge of the second part.

### CROSS-REFERENCE TO RELATED APPLICATION

This application claims priority to Chinese Patent Application No. 202410383172.5, filed on Mar. 29, 2024, the entire content of which is incorporated herein by reference.

### TECHNICAL FIELD

The present disclosure generally relates to the field of electronic device technologies and, more particularly, to an electronic device and a band.

### BACKGROUND

Currently, electronic devices with flexible displays have appeared on the market. When an electronic device is folded or flattened, the display can bend or flatten. However, during the deformation process of bending or flattening, a gap will appear between the flexible display and the frame of the electronic device, which will cause the flexible display to be easily damaged.

### SUMMARY

In accordance with the disclosure, there is provided an electronic device including a first body, a connector, a second body connected to the first body through the connector, a deformable screen including a first part fixed to the first body, a second part fixed to the second body, and a deformation part between the first part and the second part, and a deformable band covering an edge of the deformation part and including a first deformation arm including a plurality of first teeth facing toward the screen and a second deformation arm including a plurality of second teeth facing toward the screen. The first body includes a first frame covering an edge of the first part, and the second body includes a second frame covering an edge of the second part.

Also in accordance with the disclosure, there is provided a band including a main body, a first deformation arm located on a first side of the main body and including a plurality of first teeth facing toward a target direction, and a second deformation arm located on a second side of the main body that is opposite to the first side and including a plurality of second teeth facing toward the target direction.

### BRIEF DESCRIPTION OF THE DRAWINGS

To more clearly illustrate the technical solutions of the embodiments of the present disclosure, the drawings needed for use in the description of the embodiments will be briefly introduced below. The drawings described below are some embodiments of the present disclosure. For those ordinary in the art, other drawings can be obtained according to these drawings without any creative work.

FIG. 1 is a schematic structural diagram of an electronic device consistent with embodiments of the present disclosure.

FIG. 2 is an enlarged view of the portion A in FIG. 1 consistent with embodiments of the present disclosure.

FIG. 3 is a schematic partial cross-sectional view of an electronic device consistent with embodiments of the present disclosure.

FIG. 4 is a schematic diagram showing assembly of a band of an electronic device consistent with embodiments of the present disclosure.

FIG. 5 is another schematic diagram showing assembly of a band of an electronic device consistent with embodiments of the present disclosure.

FIG. 6 is another schematic diagram showing assembly of a band of an electronic device consistent with embodiments of the present disclosure.

FIG. 7 is a schematic structural diagram of an electronic device in another device state consistent with embodiments of the present disclosure.

FIG. 8 to FIG. 12 are schematic structural diagrams of bands consistent with embodiments of the present disclosure.

### REFERENCE NUMERALS

1—first body; 11—first frame; 2—connector; 3—second body; 31—second frame; 4—screen; 41—first part; 42—second part; 43—deformation part; 431—first deformation part; 432—second deformation part; 433—target position; 5—band; 51—main body; 52—first deformation arm; 53—second deformation arm; 54—tooth; 55—boss; 56—connection wall

### DETAILED DESCRIPTION OF THE EMBODIMENTS

Specific embodiments of the present disclosure are described below in detail in conjunction with the accompanying drawings, but are not intended to limit the scope of the present disclosure.

It should be understood that various modifications may be made to the embodiments disclosed herein. Therefore, the following description should not be considered limiting, but only as examples of embodiments. Those skilled in the art could think of other modifications within the scope and spirit of the present disclosure.

The accompanying drawings included in and constituting a portion of the specification illustrate embodiments of the present disclosure and are used together with the general description of the present disclosure given above and the detailed description of the embodiments given below to explain the principles of the present disclosure.

These and other features of the present disclosure may become apparent from the following description of preferred forms of embodiments given as non-limiting examples with reference to the accompanying drawings.

It should also be understood that although the present disclosure has been described with reference to some specific examples, those skilled in the art will be able to realize many other equivalent forms of the present disclosure with certainty, which have the features described in the claims and are therefore all within the scope of protection defined thereby.

The above and other aspects, features and advantages of the present disclosure will become more apparent in view of the following detailed description when combined with the accompanying drawings.

Specific embodiments of the present disclosure are described hereinafter with reference to the accompanying drawings. However, it should be understood that the disclosed embodiments are merely examples of the present disclosure, which may be implemented in a variety of ways. Well-known and/or repeated functions and structures are not described in detail to avoid unnecessary or redundant details that obscure the present disclosure. Therefore, the specific structural and functional details disclosed herein are not intended to limit, but are merely used as the basis and representative basis for the claims to teach those skilled in the art to use the present disclosure in a variety of ways with substantially any suitable detailed structure.

The phrases “in one embodiment,” “in another embodiment,” “in yet another embodiment” or “in other embodiments,” in the present disclosure, may refer to one or more of the same or different embodiments according to the present disclosure.

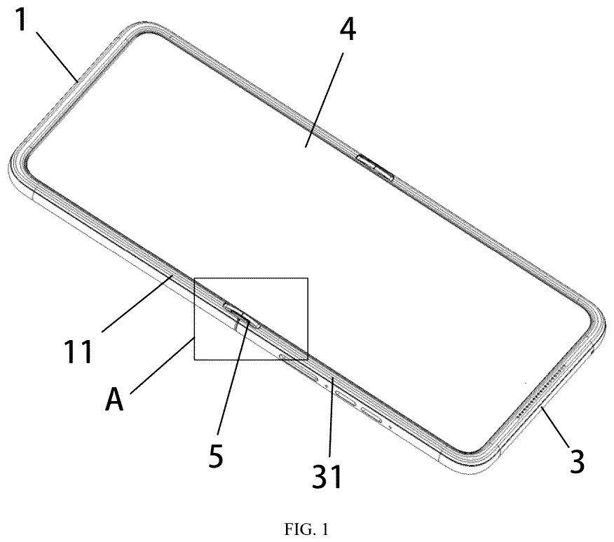

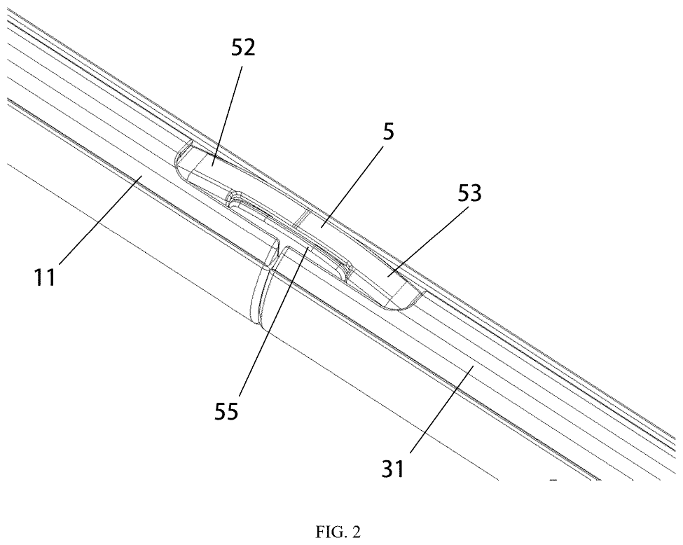

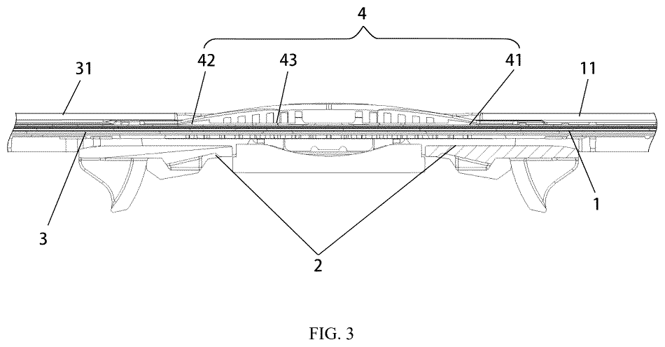

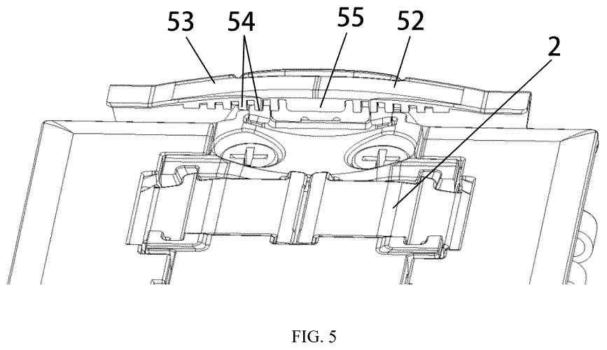

As shown in FIG. 1 to FIG. 7, the present disclosure provides an electronic device including a first body 1, a connector 2, a second body 3, a deformable screen 4, and a deformable band 5.

The second body 3 is connected to the first body 1 through the connector 2. The deformable screen 4 includes a first part 41 fixed to the first body 1, a second part 42 fixed to the second body 3, and a deformation part 43 located between the first part 41 and the second part 42. The first body 1 includes a first frame 11, and the first frame 11 covers edges of the first part 41. The second body 3 includes a second frame 31, and the second frame 31 covers edges of the second part 42. The deformable band 5 covers edges of the deformation part 43. The band 5 includes a first deformation arm 52 and a second deformation arm 53. The first deformation arm 52 includes a plurality of teeth 54 on a side facing the screen, and the second deformation arm 53 includes a plurality of teeth 54 on a side facing the screen.

The electronic device in this embodiment may be, for example, a mobile phone, a tablet computer, a monitor, or other product with the deformable screen 4. The electronic device may include the first body 1 and the second body 3. The first body 1 may be folded or flattened relative to the second body 3 through the connector 2. The front of the screen of the first part 41 may be folded close to the front of the screen of the second part 42, or may be flattened in the same plane, thereby forming a corresponding device state. The front of the screen may be a side of the screen facing the user.

For example, when the electronic device is a mobile phone, the mobile phone may be folded to form two opposite body parts, and the first body 1 and the second body 3 may be formed by the two opposite body parts, and the two body parts may be connected by the connector 2 such as a hinge mechanism. The first body 1 and the second body 3 may be relatively bent or flattened through the hinge mechanism. The display screen of the mobile phone may be the deformable screen 4, which is correspondingly arranged on the first body 1 and the second body 3. The first part 41 may be formed by a screen portion fixedly connected to the first body 1, and the second part 42 may be formed by a screen portion fixedly connected to the second body 3. The deformation part 43 may be formed between the first part 41 and the second part 42, and may correspond to the position of the connector 2. The first part 41 and the second part 42 may be stacked according to the movement of the connector 2. At this time, the front of the screen of the first part 41 may be attached to the front of the screen of the second part 42, and the front of the screen of the deformation part 43 may be bent inward accordingly. Alternatively, the first part 41 may be flattened relative to the second part 42. At this time, the front of the screen of the first part 41 and the front of the screen of the second part 42 may be on the same plane, and the screen of the deformation part 43 may be in a flattened state.

In some specific applications, the first body 1 may include a first frame 11, and the first frame 11 may wrap the first part 41 from the outer side of the first part 41. That is, the edges of the first part 41 may be covered from the front side of the deformable screen 4. The second body 3 may include a second frame 31, and the second frame 31 may wrap the second part 42 from the outer side of the second part 42. That is, the edges of the second part 42 may be covered from the front side of the deformable screen 4. In some practical applications, the size parameters of the second frame 31 and the size parameters of the first frame 11 may be set according to actual needs to achieve corresponding wrapping and shielding of their respective parts. The size parameters of the two covering the front of the screen may also be set to be the same, such that when the first body 1 and the second body 3 of the electronic device are relatively flat, the edges of the first frame 11 and the second frame 31 on the front side of the screen may be consistent to avoid a drop.

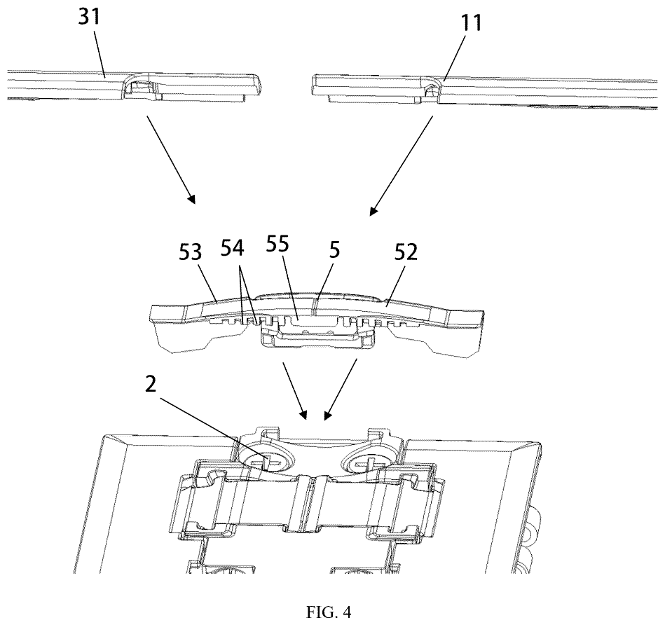

As shown in FIG. 4 to FIG. 6, to avoid affecting the folding of the screen, the edge of the deformation part of the screen 4 is not covered by the frame. The deformable band 5 in this embodiment is arranged in the front direction of the deformable screen 4, between the first frame 11 and the second frame 31, and covers the edge of the deformation part 43. The band 5 may form a cover for the edge of the deformable screen 4 together with the first frame 11 and the second frame 31 as a whole. In some specific applications, the size parameters of the deformable band 5 covering the deformation part 43 may be set in combination with the size parameters of the first frame 11 and the second frame 31 covering the front parts of the screen, to be consistent with the edge of the deformable screen 4 covered by the first frame 11 and the second frame 31. In some specific applications, the opposite sides of the deformable band 5 may include a side extending toward the first frame and a side extending toward the second frame, forming the first deformation arm 52 and the second deformation arm 53. When the deformation part 43 is bent or flattened, the first deformation arm 52 and the second deformation arm 53 may be relatively close, to fold or flatten accordingly. The first deformation arm 52 may include a plurality of teeth 54 in the direction toward the screen, and the second deformation arm 53 may include a plurality of teeth 54 in the direction toward the screen. The first deformation arm 52 and the second deformation arm 53 may be pressed against the front of the deformable screen 4 through the plurality of teeth 54. There may be corresponding gaps between teeth 54, such that when the first deformation arm 52 and the second deformation arm 53 are bent with the deformation part 43, the gaps between teeth 54 may be changed to avoid breaking, thereby extending the service life of the band 5. In some specific applications, dense and long hairs may be formed on the first deformation arm 52 and the second deformation arm 53 by electrostatic flocking. Parameters such as the diameter of a single hair may be set according to actual conditions, to form a flocking layer with multiple hairs. There may be corresponding gaps between the multiple hairs, and the multiple hairs may form the plurality of teeth 54.

In some practical applications, the deformable band 5 may be made of elastic plastic. The first deformation arm 52 and the second deformation arm 53 may press the edge of the deformation part 43 when the deformation part 43 is flattened. When the deformation part 43 is bent, the first deformation arm 52 and the second deformation arm 53 may bend accordingly with the bending of the deformation part 43, and the elastic force provided by the deformable band 5 may enable the first deformation arm 52 and the second deformation arm 53 to maintain the pressure on the edge of the deformation part 43.

Further, the deformable band 5 may include a boss 55 in the direction toward the screen, and the boss 55 may press against the screen. During the deformation process of bending or flattening, the deformable screen 4 may maintain pressure against the screen through the boss 55, and the deformation part 43 may be deformed based on the pressure point between the boss 55 and the screen, to prevent the deformation part 43 from bulging during the bending process. Or, when the deformation part 43 generates water ripples during the deformation process, the force may be transmitted to the boss 55, thereby avoiding damage to the screen.

In some embodiments, the electronic device may at least have a first device state and a second device state.

When the first body 1 and the second body 3 are in the first device state through the connector 2, the first part 41 and the second part 42 of the screen may belong to the same plane, and the boss 55 may press against the target position 433 of the deformation part 43.

When the first body 1 and the second body 3 are in the second device state through the connector 2, the first part 41 of the screen and the second part 42 of the screen may be stacked, and the boss 55 may press against the target position 433 of the deformation part 43.

The deformation part 43 may change as the electronic device changes between the first device state and the second device state.

The first deformation arm 52 may change as the electronic device changes between the first device state and the second device state.

The second deformation arm 53 may change as the electronic device changes between the first device state and the second device state.

The device state may be used to characterize the relative position relationship between the first body 1 and the second body 3. The electronic device may change the relative position relationship between the first body 1 and the second body 3 by moving the connector 2, to switch between the first device state and the second device state. The first device state may represent that the first body 1 and the second body 3 are in a flattened state through the connector 2. At this time, the deformation part 43 may be in a flattened state, and the first part 41 corresponding to the first body 1 and the second part 42 corresponding to the second body 3 may be in a flattened state, and together with the deformation part 43, they may be constructed into a flat plane. The second device state may represent that the first body 1 and the second body 3 are in a folded state through the connector 2. At this time, the first part 41 corresponding to the first body 1 and the second part 42 corresponding to the second body 3 may be stacked, and the two sides of the deformation part 43 may be in a bent state with the stacking of the first part 41 and the second part 42.

It can be understood that the deformable screen 4 may realize the stacking of the first part 41 and the second part 42 by the deformation of the deformation part 43. When the two sides of the deformation part 43 are relatively bent, the central area thereof may need to maintain a relatively stable state. Therefore, the target position 433 of the deformation part 43 may be the position corresponding to the central area thereof at the edge part.

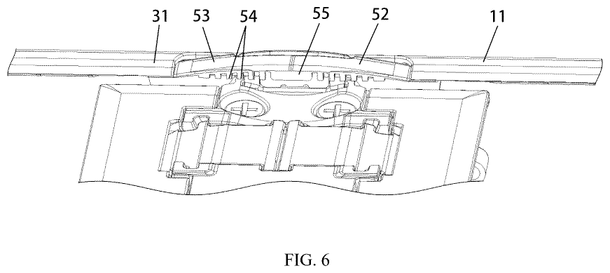

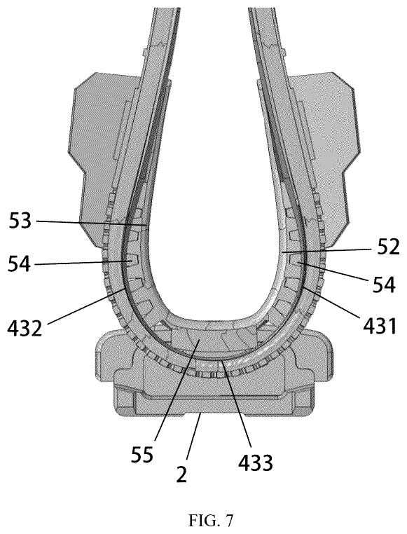

FIG. 6 and FIG. 7 show the state of the band in the electronic device under different device states. As shown in FIG. 6 and FIG. 7, in this embodiment, when the electronic device is in the first device state, the deformation part 43 is in a flattened state, and the boss 55 is pressed against the central area of the deformation part 43. When the electronic device is in the second device state, the deformation part 43 is in a bent state, the relative positional relationship between the boss 55 and the central area of the deformation part 43 remains unchanged, and the two maintain a state of pressing against each other. Therefore, in the process of switching the device state of the electronic device, the deformation part 43 may be stably bent based on the pressure of the boss 55 on the central area.

Therefore, in this embodiment, when the electronic device switches between the first device state and the second device state through the connector 2, the boss 55 of the deformable band 5 may maintain the pressure on the target position 433 of the deformation part 43. The two sides of the deformation part 43 connected to the first part 41 and the second part 42 may change with the flattened posture or folded posture of the electronic device, that is, may flatten or bend accordingly. The first deformation arm 52 and the second deformation arm 53 on two sides of the deformable band 5 may correspond to the two sides of the deformation part 43 respectively. When the two sides of the deformation part 43 are flattened or bent, the first deformation arm 52 and the second deformation arm 53 may be flattened or bent accordingly as the two sides of the deformation part 43 are relatively flattened or bent.

In some embodiments, when the first body 1 and the second body 3 are in the second device state through the connector 2, the plurality of teeth 54 of the first deformation arm 52 may be used to support the first deformation part 431, and the plurality of teeth 54 of the second deformation arm 53 may be used to support the second deformation part 432. The deformation part 43 may include a first deformation part 431 from the target position 433 to the first part 41 and a second deformation part 432 from the target position 433 to the second part 42.

In this embodiment, the deformation part 43 may be divided into two sub-deformation parts 43 according to the target position 433, namely the first deformation part 431 and the second deformation part 432. A portion of the screen corresponding to the deformation part 43 extending from the target position 433 to the first part 41 may be the first deformation part 431, and a portion of the screen extending from the target position 433 to the second part 42 may be the second deformation part 432. When the electronic device is in the folded state, the first part 41 and the second part 42 of the screen may be stacked, and the deformation part 43 may be in a bent state, that is, the first deformation part 431 and the second deformation part 432 may be bent relative to each other with the target position 433 as the base point, such that the first deformation arm 52 and the second deformation arm 53 are bent accordingly with the boss 55 as the base point. The elastic force provided by the deformable band 5 may enable the first deformation arm 52 to press the first deformation part 431 through the plurality of teeth 54 provided thereon, and the second deformation arm 53 may press the second deformation part 432 through the plurality of teeth 54 provided thereon. Therefore, in the folded state of the electronic device, in the bending space formed by the bending of the first deformation part 431 and the second deformation part 432, the first deformation arm 52 and the second deformation arm 53 may respectively press the first deformation part 431 and the second deformation part 432 to provide support force toward the outside of the bending space for the first deformation part 431 and the second deformation part 432. When receiving an external force impact (for example, when the electronic device falls), the bending space formed by the bending of the first deformation part 431 and the second deformation part 432 may be supported by the pressure provided by the first deformation arm 52 and the second deformation arm 53, respectively, to prevent the screen of the deformation part 43 from being subjected to free oscillation deformation because of impact force or inertia when receiving the external force impact, thereby avoiding damage to the screen caused thereby.

In some embodiments, the thickness of the boss 55 may be larger than the thickness of the plurality of teeth 54 of the first deformation arm 52, and the thickness of the boss 55 may be larger than the thickness of the plurality of teeth 54 of the second deformation arm 53. In this embodiment, the thickness of the boss 55 may be larger than the thickness of each tooth 54, such that when the band 5 is pressed against the screen and subjected to force, the boss 55 is not easily deformed relative to each tooth 54. Therefore, when the deformation part 43 of the screen is bent, the first deformation arm 52 and the second deformation arm 53 may be bent accordingly with the bending of the deformation part 43, and the plurality of teeth 54 may be deformed accordingly when they abut against the screen of the deformation part 43, thereby supporting the screen. Further, the thickness of the boss 55 may be used to prevent the boss from deforming or make it only slightly deform, such that the relative position between the boss 55 and the target position 433 does not change, thereby maintaining the pressure of the boss 55 on the screen.

In some embodiments, the thickness of the plurality of teeth 54 of the first deformation arm 52 may gradually decrease from the boss 55 to the end of the first deformation arm 52, and the thickness of the plurality of teeth 54 of the second deformation arm 53 may gradually decrease from the boss 55 to the end of the second deformation arm 53.

It can be understood that the deformable band 5 may press the screen at the edge of the deformation part 43 through the boss 55, and the two ends may respectively press the screen at the edge of the deformation part 43 through the plurality of teeth 54 of the first deformation arm 52 and the second deformation arm 53. Since the thickness of the boss 55 is larger than the thickness of the plurality of teeth 54, the band 5 may form two spaces with gradually decreasing heights relative to the screen in the directions of the two sides extending to the first frame 11 and the second frame 31. To achieve a smooth transition from the band 5 to the first frame 11, the thickness of the plurality of teeth 54 of the first deformation arm 52 may gradually decrease from the boss 55 to the end of the first deformation arm 52, that is, a first tooth 54 close to the boss 55 among the plurality of teeth 54 of the first deformation arm 52 may be the thickest, and the thickness values of subsequent teeth 54 gradually decrease until the thickness value of the last tooth 54 at the end of the first deformation arm 52 is the smallest. The first deformation arm 52 may form a wedge-shaped structure as a whole, such that when the first deformation arm 52 is connected to the first frame 11, the height of the first deformation arm 52 relative to the screen and the height of the first frame 11 relative to the screen may be prevented from presenting an obvious step-like shape. Correspondingly, the thickness of the plurality of teeth 54 of the second deformation arm 53 may gradually decrease from the boss 55 to the end of the second deformation arm 53, that is, a first tooth 54 close to the boss 55 among the plurality of teeth 54 of the second deformation arm 53 may be the thickest, and the thickness values of the subsequent teeth 54 may gradually decrease until the thickness value of the last tooth 54 at the end of the second deformation arm 53 is the smallest. The second deformation arm 53 may form a wedge-shaped structure as a whole, such that the second deformation arm 53 may have a smooth transition when connected to the second frame 31, thereby preventing the height of the second deformation arm 53 relative to the screen and the height of the second frame body 31 relative to the screen from presenting an obvious step-like shape.

In some embodiments, the plurality of teeth 54 of the first deformation arm 52 may form at least one first blocking rib along the first deformation arm 52, and the at least one first blocking rib may be arranged in parallel, and teeth 54 of the at least one first blocking rib may be staggered with each other.

The plurality of teeth 54 of the second deformation arm 53 may form at least one second blocking rib along the second deformation arm 53. The at least one second blocking ribs may be arranged in parallel, and the teeth 54 of the at least one second blocking rib may be staggered with each other.

In this embodiment, the plurality of teeth 54 of the first deformation arm 52 may be aligned and arranged in sequence along the direction from the boss 55 to the end, and one first blocking rib may be formed by the plurality of teeth 54 arranged in a row. The gap between the teeth 54 may be set according to the actual situation. Correspondingly, the plurality of teeth 54 of the second deformation arm 53 may be aligned and arranged in sequence along the direction from the boss 55 to the end, and one second blocking rib may be formed by the plurality of teeth 54 arranged in a row. The gap between the teeth 54 may be set in combination with the setting method of the first blocking rib. Thus, the deformable band 5 may block the entry of external particles and foreign matter through the first blocking rib and the second blocking rib, avoiding the problem of poor screen display effect or screen damage caused by this, and achieving a dustproof effect.

Further, in the process of bending the deformation part 43, the first deformation arm 52 may be driven to move toward the middle and press the teeth 54, which may cause the teeth 54 to be skewed and deformed, resulting in the gap between the teeth 54 becoming larger. To solve this technical problem, in some specific applications, the plurality of teeth 54 of the first deformation arm 52 may be arranged in a plurality of rows along the direction from the boss 55 to the end, and a plurality of first blocking ribs may be correspondingly formed by the plurality of teeth 54 arranged in the plurality of rows. Teeth 54 of the plurality of first blocking ribs may be staggered with each other. For example, there may be gaps between the plurality of teeth 54 of a first one of the plurality of first blocking ribs, and the teeth 54 of the second one of the plurality of first blocking ribs may be arranged corresponding to the gaps between the plurality of teeth 54 of the first one of the plurality of first blocking ribs, and the teeth 54 of the third one of the plurality of first blocking ribs may be arranged corresponding to the gaps between the plurality of teeth 54 of the second one of the plurality of first blocking ribs.

Correspondingly, the plurality of teeth 54 of the second deformation arm 53 may be arranged in a plurality of rows along the direction from the boss 55 to the end, and a plurality of second blocking ribs may be correspondingly formed by the plurality of teeth 54 arranged in the plurality of rows. The teeth 54 of the plurality of second blocking ribs may be arranged staggered with each other. For example, there may be gaps between the plurality of teeth 54 of the first one of the plurality of second blocking ribs, the teeth 54 of the second one of the plurality of second blocking ribs may be arranged corresponding to the gaps between the plurality of teeth 54 of the first one of the plurality of second blocking ribs, and the teeth 54 of the third one of the plurality of second blocking ribs may be arranged corresponding to the gaps between the plurality of teeth 54 of the second one of the plurality of second blocking ribs.

Thus, the deformable band 5 may block the foreign particles entering from the gaps between the teeth 54 of the first one of the plurality of first blocking ribs and the first one of the plurality of second blocking ribs through the teeth 54 of the second one of the plurality of first blocking ribs and the second one of the plurality of second blocking ribs, by respectively arranging the plurality of parallel first blocking ribs and second blocking ribs, thereby achieving the beneficial effect of blocking the foreign particles layer by layer, and improving the dustproof effect of the deformable band 5.

In some embodiments, the first frame 11 may cover a portion of the first deformation arm 52, and the first deformation arm 52 may be movably connected to the first frame 11. The second frame 31 may cover a portion of the second deformation arm 53, and the second deformation arm 53 may be movably connected to the first frame 11.

It can be understood that in this embodiment, the first frame 11 and the second frame 31 may cover the screen edges of the first part 41 and the second part 42 from the front of the screen respectively. When the deformable band 5 covers the edge of the deformation part 43, the first deformation arm 52 and the second deformation arm 53 may extend from the corresponding side to the edge of the first part 41 and the edge of the second part 42 respectively, to be connected with the first frame 11 and the second frame 31 at the corresponding position. In this embodiment, to limit the two sides of the deformable band 5, the end of the first deformation arm 52 may be extended between the edge of the first frame 11 and the first part 41 along the direction from the deformation part 43 to the first part 41, and movably connected with the first frame 11. Correspondingly, the end of the second deformation arm 53 may be extended between the edge of the second frame 31 and the second part 42 along the direction from the deformation part 43 to the second part 42, and movably connected with the second frame 31.

Exemplarily, to realize the movable connection of the first deformation arm 52, the first frame 11 located on the front of the screen may be provided with an oblong first limit hole on the side facing the screen, and a first limit part with matching size may be provided at the relative position of the first deformation arm 52. The first limit part may extend into the first limit hole and slide into the first limit hole. Therefore, when the first deformation arm 52 is bent along with the deformation part 43, the first limit part may move in the first limit hole in the direction toward the deformation part 43, such that the portion of the first deformation arm 52 exposed on the screen may be extended. When the first deformation arm 52 is flattened along with the deformation part 43, the first limit part may move in the first limit hole in the direction away from the deformation part 43, such that the portion of the first deformation arm 52 exposed on the screen may be shortened to avoid the phenomenon of arching. The movable connection method for the second deformation arm 53 may refer to the movable connection method of the first deformation arm 52 and combine with the second frame 31 for corresponding implementation, which will not be repeated here.

In some embodiments, the deformable band 5 may further include: a connection wall 56, which is used to be fixedly connected to the connector 2. The connection wall 56 and the boss 55 may be located on the same side of the deformable band 5, and the connection line between the connection wall 56 and the boss 55 on the deformable band 5 may be perpendicular to the surface where the connection wall 56 is located.

In this embodiment, to assemble the deformable band 5, the deformable band 5 may be provided with a connection wall 56 at a position corresponding to the connector 2, and the size parameters of the connection wall 56 may be adaptively set according to the gap that is reserved in the connector 2, so that the connection wall may be fixedly connected to the connector 2 through the reserved gap. For example, the connection wall 56 and the boss 55 may be both located on the side of the deformable band 5 facing the screen, and the connection line between the deformable band 5 and the deformable screen 4 may be parallel to the surface where the connection wall 56 is located. The boss 55 may be adapted to press against the edge of the screen based on its thickness. The thickness of the connection wall 56 may be larger than that of the boss 55, and the connection wall 56 may extend downward along the edge of the screen to the connector 2 to be fixedly connected with the connector 2. Exemplarily, in actual applications, the connector 2 may include a moving component and a connector shell for mounting the moving component. The connection wall 56 may extend into the gap between the moving component and the connector shell, and may be fixed to the moving component. The fixing method of the connection wall 56, may include that, for example, a hook may be provided on the connection wall 56, a corresponding slot may be provided on the moving component, and the connection wall 56 may be fixed in the gap between the moving component and the connector shell by the cooperation of the hook and the slot. For another example, a glue dispensing groove may be provided in the gap between the moving component and the connector shell, and glue may be injected into the glue dispensing groove, and then the connection wall 56 may be extended into the glue dispensing groove in the gap between the moving component and the connector shell, such that the connection wall 56 may be fixed by glue.

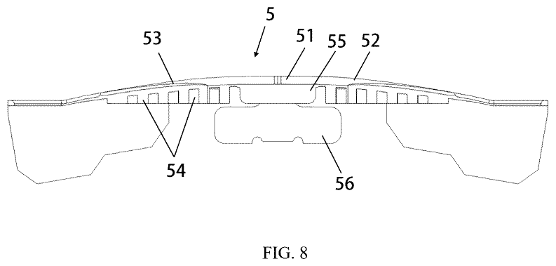

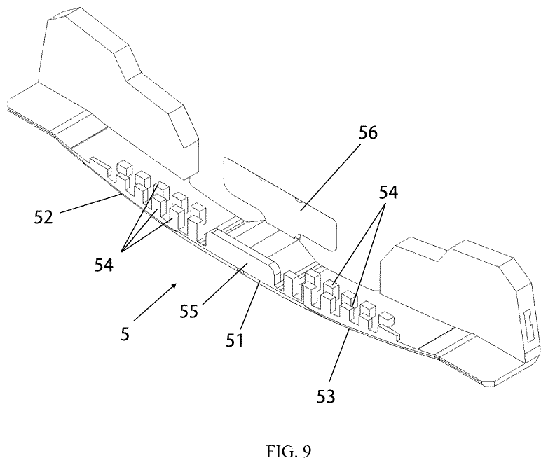

As shown in FIG. 8 to FIG. 12, the present disclosure also provides a band 5, including:
a main body 51,
a first deformation arm 52, located on a first side of the main body 51 and including a plurality of teeth 54 facing a target direction; and
a second deformation arm 53, located on a second side of the main body 51 and including a plurality of teeth 54 facing the target direction, where the first side is opposite to the second side.

The band 5 may be used to press against the surface of a deformable target object, and may be deformed accordingly with the deformation of the target object. The target object may be, for example, the edge of the deformation part 43 of the deformable screen 4. Therefore, it can be understood that the band 5 may have a pressing surface for pressing against the target object, and the target direction may be the direction of the band 5 facing the pressing surface.

In the present disclosure, the band 5 may mainly include the main body 5, and the first deformation arm 52 and the second deformation arm 53 arranged on opposite sides of the main body 51. After the band 5 is assembled, the first deformation arm 52 and the second deformation arm 53 may be correspondingly located on two sides of the target object where the relative deformation occurs. When subjected to the extrusion force generated when the target object is bent and deformed, the first deformation arm 52 and the second deformation arm 53 may be folded and deformed relative to the main body 51 along the deformation direction of the target object. For example, the first deformation arm 52 may include the plurality of teeth 54 facing the target direction, and the second deformation arm 53 may include the plurality of teeth 54 facing the target direction. There may be corresponding gaps between teeth 54 of the first deformation arm 52 and the second deformation arm 53. When the first deformation arm 52 and the second deformation arm 53 are bent along with the target object, the gaps between the teeth 54 may become larger, thereby avoiding breakage by changing the gaps between the teeth 54.

In some specific applications, the main body 51, the first deformation arm 52, and the second deformation arm 53 of the band 5 may be made of elastic plastic. The first deformation arm 52 and the second deformation arm 53 may be deformed under pressure and provide a certain elastic force to return to the initial position. When the first deformation arm 52 and the second deformation arm 53 are bent, the gap between the teeth 54 may become larger, thereby preventing the plastic layer from being easily broken and extending the service life of the band 5.

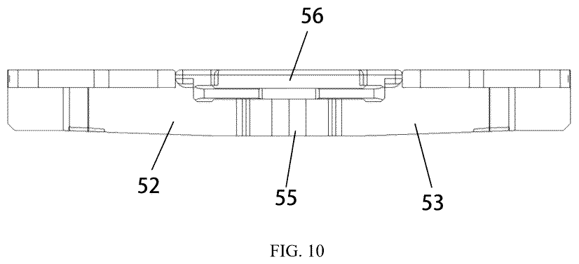

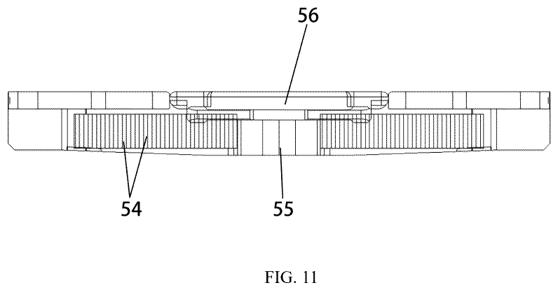

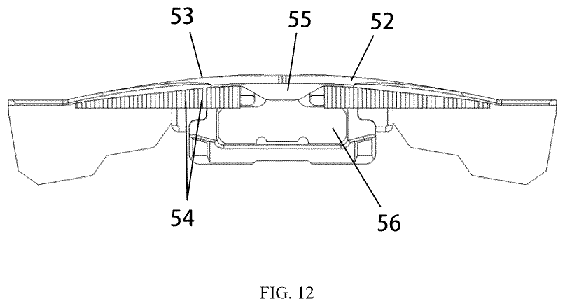

The schematic structural diagrams of the band in FIG. 10 to FIG. 12 show the process of forming teeth by electrostatic flocking in one embodiment. FIG. 10 shows the first deformation arm 52 and the second deformation arm 53 of the band. As shown in FIG. 11, the first deformation arm 52 and the second deformation arm 53 are flocked by electrostatic flocking to form dense long hair. The diameter and length of a single hair may be set according to actual needs. Finally, a flocking layer with a plurality of hair may be formed. There may be corresponding gaps between the plurality of hair, and each hair may form multiple teeth 54 of this embodiment. From FIG. 12, it can be seen that the multiple teeth 54 formed by the slender hair are more soft, and the multiple rows of hair in the flocking layer may block small particles of foreign matter and even dust from the outside, thereby improving the effect of dust prevention and foreign matter prevention. Further, when the electronic device is in a closed state, the long hair may also contact the water drop-shaped deformation part on the screen to protect the water drop-shaped deformation part.

In some embodiments, the band 5 may further include:
a connection wall 56, used for assembly connection; and
a boss 55, used for limiting the movement of a target member.

The connection wall 56 may be formed by a part of the main body 51 protruding in the target direction; and the boss 55 may be formed by a part of the main body 51 protruding in the target direction.

In this embodiment, to assemble and connect the band 5, the main body 51 may be formed with the connection wall 56 facing toward the target direction. The connection wall 56 may be made of the same material as the main body 51. Optionally, to achieve a stable connection of the band 5, the connection wall 56 may also be made of metal material. The boss 55 may be made of the same material as the main body 51. The target member of this embodiment may be the target object pressed by the band 5, such as the deformation part 43 of the screen in the aforementioned embodiment. For example, after the band 5 is assembled with the electronic device, the boss 55 may be pressed against the deformation part 43 of the screen. During the bending or flattening process, the deformation part 43 may be bent and deformed based on the pressing point between the boss 55 and the screen to avoid vibration or arching of the deformation part 43, thereby realizing the limit by the boss 55 to the movement of the deformation part 43 of the target member.

In some specific applications, considering that the boss 55 is used to press the target member, the connection wall 56 may need to extend beyond the connector, and the thickness of the connection wall 56 may be larger than the thickness of the boss 55 to facilitate fixation.

Exemplary embodiments of the present disclosure have been described herein. The scope of the present disclosure includes any and all embodiments based on the exemplary embodiments with equivalent elements, modifications, omissions, combinations (e.g., cross-schemes of various embodiments), adaptations or changes. The elements in the claims may be interpreted broadly based on the language used in the claims and are not limited to the examples described in the present disclosure or during the execution of the present disclosure. The examples should be interpreted as non-exclusive. Therefore, the present disclosure and examples are intended to be considered as examples only, and the true scope and spirit of the present disclosure are indicated by the following claims and the full scope of their equivalents.

The above description is intended to be illustrative rather than restrictive. For example, the above examples (or one or more schemes thereof) may be used in combination with each other. For example, those ordinary skilled in the art may use other embodiments when reading the above description. In addition, in the above detailed description, various features may be grouped together to simplify the present disclosure. This should not be interpreted as an intention that a disclosed feature that is not claimed for protection is necessary for any claim. On the contrary, the subject matter of the present disclosure may be less than all the features of a specific disclosed embodiment. Thus, the following claims are incorporated into the detailed description as examples or embodiments, where each claim is independently a separate embodiment, and it is considered that these embodiments can be combined with each other in various combinations or arrangements. The scope of the present disclosure shall be determined by reference to the attached claims and the full scope of equivalent forms granted by these claims.

The above embodiments are only exemplary embodiments of the present disclosure and are not intended to limit the present disclosure. The scope of protection of the present disclosure is defined by the claims. Those skilled in the art may make various modifications or equivalent substitutions to the present disclosure within the essence and scope of protection of the present disclosure, and such modifications or equivalent substitutions shall also be deemed to fall within the scope of the present disclosure.

What is claimed is:

1. An electronic device comprising:
a first body;
a connector;
a second body connected to the first body through the connector;
a deformable screen, including a first part fixed to the first body, a second part fixed to the second body, and a deformation part between the first part and the second part; and
a deformable band covering an edge of the deformation part and including:
a first deformation arm including a plurality of first teeth facing toward the screen; and
a second deformation arm including a plurality of second teeth facing toward the screen;
wherein:
the first body includes a first frame covering an edge of the first part; and
the second body includes a second frame covering an edge of the second part.

2. The electronic device according to claim 1, wherein the deformable band further includes a boss on a side facing the screen and configured to press against the screen.

3. The electronic device according to claim 2, wherein:
the electronic device at least has:
a first device state, in which the first part and the second part are located in a same plane, and the boss presses against a target position of the deformation part; and
a second device state, in which the first part and the second part are stacked, and the boss presses against the target position; and
the deformation part, the first deformation arm, and the second deformation arm are configured to change as the electronic device changes between the first device state and the second device state.

4. The electronic device according to claim 3, wherein:
the deformation part includes a first deformation part extending from the target position towards the first part and a second deformation part extending from the target position towards the second part; and
the plurality of first teeth are configured to support the first deformation part when the electronic device is in the second device state, and the plurality of second teeth are configured to support the second deformation part when the electronic device is in the second device state.

5. The electronic device according to claim 2, wherein a thickness of the boss is larger than a thickness of each of the plurality of first teeth and the plurality of second teeth.

6. The electronic device according to claim 5, wherein:
thicknesses of the plurality of first teeth gradually decrease from the boss to an end of the first deformation arm; and
thicknesses of the plurality of second teeth gradually decrease from the boss to an end of the second deformation arm.

7. The electronic device according to claim 1, wherein:
the plurality of first teeth form a plurality of first blocking ribs arranged in parallel and each extending along the first deformation arm, teeth of the plurality of first blocking ribs being staggered with each other; and
the plurality of second teeth form a plurality of second blocking ribs arranged in parallel and each extending along the second deformation arm, teeth of the plurality of second blocking rib being staggered with each other.

8. The electronic device according to claim 1, wherein:
the first frame covers a portion of the first deformation arm, and the first deformation arm is movably connected to the first frame; and
the second frame covers a portion of the second deformation arm, and the second deformation arm is movably connected to the first frame.

9. The electronic device according to claim 1, wherein:
the deformable band further includes a boss configured to press against the screen and a connection wall configured to be fixedly connected to the connector;
the connection wall and the boss are located on a same side of the deformable band; and
a connection line between the connection wall and the boss on the deformable band is perpendicular to a surface where the connection wall is located.

10. A band comprising:
a main body,
a first deformation arm, located on a first side of the main body and including a plurality of first teeth facing toward a target direction; and
a second deformation arm, located on a second side of the main body that is opposite to the first side, and including a plurality of second teeth facing toward the target direction.

11. The band according to claim 10, further comprising:
a connection wall formed by a portion of the main body protruding toward a target direction and for assembly and connection; and
a boss formed by a portion of the main body protruding toward the target direction and configured to limit movement of a target member.
